(19) United States
(12) Patent Application Publication
(10) Pub. No.: US 2006/0164153 A1
(43) Pub. Date: Jul. 27, 2006

(54) Characteristic adjustment circuit for logic circuit, circuit, and method of adjusting a characteristic of circuit

(75) Inventor: Hisashi Yamashida, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Corporation, Tokyo (JP)

(21) Appl. No.: 11/338,632

(22) Filed: Jan. 25, 2006

(30) Foreign Application Priority Data
Jan. 26, 2005 (JP) 2005-017560

(51) Int. Cl. H03K 3/01

(52) U.S. Cl. 327/534

(57) ABSTRACT

A characteristic adjustment circuit for a logic circuit includes an oscillator that includes a first metal-oxide semiconductor (MOS) transistor and outputs an oscillation output, and a voltage generator that generates a voltage of a second MOS transistor of the logic circuit according to a phase difference between the oscillation output and a reference signal.

### BACKGROUND OF THE INVENTION

1. Field of the Invention

The present invention relates to a characteristic adjustment circuit for a logic circuit and a method thereof, and a circuit (e.g., a semiconductor integrated circuit) using the logic circuit. For example, the present invention relates to a characteristic adjustment method for a logic circuit within a semiconductor integrated circuit having a MOS (metal oxide semiconductor) logic circuit.

2. Conventional Art

For example, due to a variation of transistor characteristics during manufacture of a circuit (e.g., a semiconductor integrated circuit (IC)) associated with recent miniaturization of semiconductor ICs, such as a temperature change and a power supply voltage change, the driving capacity of a MOS transistor (e.g., P-channel and N-channel MOS transistors) fluctuates. Consequently, circuit characteristics (e.g., delay time) of a logic circuit including these and other transistors fluctuate, thus causing a variation of the logic circuit's operation and performance.

Japanese Patent Laid-Open No. 8-23271, discloses a technique of adjusting the delay time of a transistor caused by a variation of a MOS transistor, a temperature change, a power supply voltage change, etc. In this technique, a delay difference between two delay circuits having a different number of stages is converted to a voltage level. The voltage level is compared with an external reference voltage and the back bias voltage of the MOS transistor is adjusted according to the comparison result, whereby the delay time is automatically adjusted.

### SUMMARY OF THE INVENTION

### Exemplary Problems to be Solved by the Invention

In the technique disclosed in Japanese Patent Laid-Open No. 8-23271, the back bias voltage of transistor is controlled so that the delay time itself of the delay circuit becomes a predetermined value. As described above, however, it is impossible to suppress a variation in circuit characteristics, including delay time etc., of all logic circuits within a semiconductor IC.

Japanese Patent Laid-Open No. 5-342868 discloses a technique of adjusting highly accurately the bias voltage, i.e., the back bias voltage supplied to a semiconductor substrate in a semiconductor IC. However, a variation of characteristic(s) of all logic circuits within the semiconductor IC cannot be suppressed.

In view of the foregoing and other exemplary problems, drawbacks, and disadvantages of the conventional techniques, it is an exemplary feature of the present invention to provide a characteristic adjustment circuit and a method thereof which may suppress a variation in circuit characteristics (e.g., delay time, etc). of a logic circuit, and a circuit (e.g., a semiconductor integrated circuit) using the logic circuit.

Another exemplary feature of the present invention is to provide a characteristic adjustment circuit and a method thereof which may exceedingly accurately perform the adjustment of delay time of a logic circuit within a logic circuit, and a circuit (e.g., a semiconductor integrated circuit) using the logic circuit.

The present invention provides a characteristic adjustment circuit for a logic circuit, including an oscillator that includes a first metal-oxide semiconductor (MOS) transistor and outputs an oscillation output, and a voltage generator that generates a voltage of a second MOS transistor of the logic circuit according to a phase difference between the oscillation output and a reference signal.

The present invention also provides a circuit including the logic circuit, and the characteristic adjustment circuit described above.

The present invention also provides a characteristic adjustment circuit including a ring oscillator that includes a first metal-oxide semiconductor (MOS) transistor and outputs an oscillation output, and a voltage generator that generates a voltage of a second MOS transistor of the logic circuit according to the oscillation output.

The present invention also provides a method of adjusting a characteristic of a logic circuit, including detecting a phase difference between a reference signal and an oscillation output of an oscillator including a first metal-oxide semiconductor (MOS) transistor, and generating a voltage of a second MOS transistor of the logic circuit according to the phase difference.

The present invention also provides a method of adjusting a characteristic of a logic circuit, including outputting an oscillation output by a ring oscillator including a first metal-oxide semiconductor MOS transistor, and generating a voltage of the second MOS transistor of the logic circuit according to the oscillation output.

### EXEMPLARY ADVANTAGES OF THE INVENTION

For example, according to the present invention, a variation of circuit characteristic (e.g., delay time) of a logic circuit caused by a variation in a circuit manufacturing process (e.g., semiconductor IC manufacturing process) and/or by a variation of external environment conditions (e.g., temperature and power supply voltage) may automatically be adjusted.

This is because a characteristic adjustment circuit for a logic circuit includes an oscillator that includes a first metal-oxide semiconductor (MOS) transistor and outputs an oscillation output, and a voltage generator that generates a voltage of a second MOS transistor of the logic circuit according to a phase difference between the oscillation output and a reference signal.

### BRIEF DESCRIPTION OF THE DRAWINGS

The novel and exemplary features believed characteristic of the invention are set forth in the appended claims. The invention itself, however, as well as other exemplary features and advantages thereof, will be best understood by reference to the detailed description which follows, read in conjunction with the accompanying drawings, wherein:

FIG. 1 shows an exemplary block diagram showing an exemplary embodiment of the present invention;

FIG. 2 shows an exemplary timing chart showing an exemplary operation of the present invention;

FIG. 3 shows an exemplary view showing an exemplary delay element 100 in ring oscillator 1 of FIG. 1;

FIG. 4 shows an exemplary view showing an exemplary delay element 101 in ring oscillator 1 of FIG. 1;

FIG. 5 shows an exemplary view showing an exemplary delay element 102 in ring oscillator 1 of FIG. 1;

FIG. 6 shows an exemplary view showing the exemplary ring oscillator 1; and

FIG. 7 shows an exemplary block diagram showing another exemplary embodiment of the present invention.

### DETAILED DESCRIPTION OF THE EXEMPLARY EMBODIMENTS

According to the present invention, for example, a phase difference is detected between a predetermined reference clock and an oscillation output of a ring oscillator using a delay element including a MOS transistor, that may be substantially identical to that used in an internal MOS-type logic circuit whose characteristics are to be adjusted. Then, for example, the back gate voltage of MOS transistor is controlled according to the phase difference, whereby characteristics, including delay time of the internal logic circuit, may be uniformly controlled at all times.

For example, by using the logic circuit element within the semiconductor IC whose delay time may be adjusted, as the delay element constituting the ring oscillator, the difference of effect based on the kind of logic circuit with respect to the back gate voltage control may be reduced.

### Exemplary Embodiment

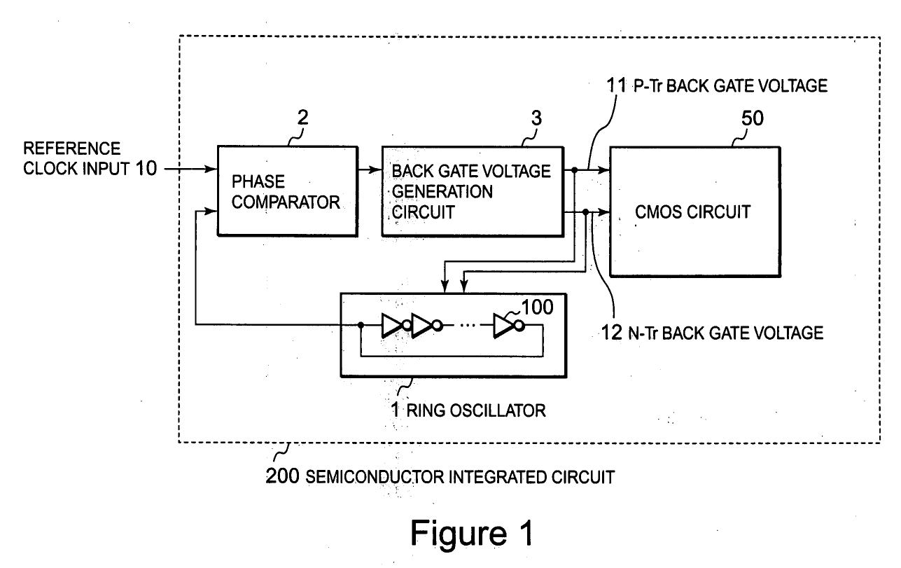

Exemplary embodiments of the present invention will be described below. FIG. 1 shows an exemplary block diagram showing an exemplary embodiment of the present invention. Referring to FIG. 1, for example, ring oscillator 1 including plural delay elements 100 connected in a ring configuration is provided, and the oscillation frequency of ring oscillator 1 is supplied to phase comparator 2 to perform a frequency comparison and a phase comparison with reference clock input 10.

For example, the comparison result may be supplied to a voltage generation circuit (e.g., back gate voltage generation circuit 3). According to the comparison result, voltage (e.g., back gate voltages 11 and 12) of CMOS logic circuit 50 may be generated. For example, reference numeral 11 may denote the back gate voltage of P-channel transistor (P-Tr), and reference numeral 12 may denote the back gate voltage of N-channel transistor (N-Tr).

For example, voltages (e.g., back gate voltages 11 and 12) are distributed over all CMOS logic circuits 50 that constitute a semiconductor integrated circuit 200. All CMOS logic circuits 50 are operated by the voltages (e.g., back gate voltages 11 and 12). For example, back gate voltages 11 and 12 are obtained by coinciding an oscillating frequency of ring oscillator 1 including a CMOS circuit, with reference clock input 10 input from outside of semiconductor integrated circuit 200.

Ring oscillator 1, phase comparator 2, back gate voltage generation circuit 3 and CMOS logic circuit 50 may be formed on a single IC substrate by a CMOS transistor constitution.

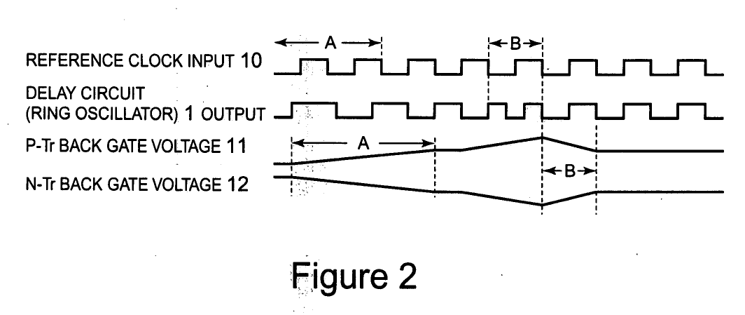

FIG. 2 shows an exemplary timing chart showing an exemplary operation of the present invention shown in FIG. 1.

In the above exemplary configuration, the phase comparator 2 performs a phase comparison between reference clock input 10 and the oscillation signal of the ring oscillator (delay circuit) 1 including the delay elements 100 formed of a CMOS logic circuit, connected in series and in a ring configuration.

When the delay time of the oscillation signal is relatively larger (e.g., the oscillation signal is delayed as compared with the reference clock 10; range “A” in FIG. 2), a phase comparison output is generated so that the phase of oscillation signal is advanced, for example, so that P-Tr back gate voltage 11 of CMOS logic circuit 50 is raised and N-Tr back gate voltage 12 of CMOS logic circuit 50 is lowered.

When the delay time of the oscillation signal is relatively smaller (e.g., the oscillation signal is advanced as compared with the reference clock 10; range “B” in FIG. 2), a phase comparison output is generated so that the phase of oscillation signal is delayed, for example, so that P-Tr back gate voltage 11 is lowered and N-Tr back gate voltage 12 is raised. In response to the phase comparison output, the output voltage of back gate voltage generation circuit 3 varies.

As a result, the oscillation frequency of ring oscillator 1 is also controlled. The feedback control is performed until the oscillation frequency of ring oscillator 1 coincides with the frequency of reference clock input 10.

By performing such an operation that is shown as an example, a variation of delay time of a logic circuit caused by a variation in IC manufacturing process and/or by a variation of environment conditions, such as temperature, voltage, etc., may be adjusted automatically and highly accurately.

Phase comparator 2 may compare an oscillating signal of a delay circuit (e.g., ring oscillator 1) that is formed of a series-connected CMOS logic circuit with the phase of reference clock input 10.

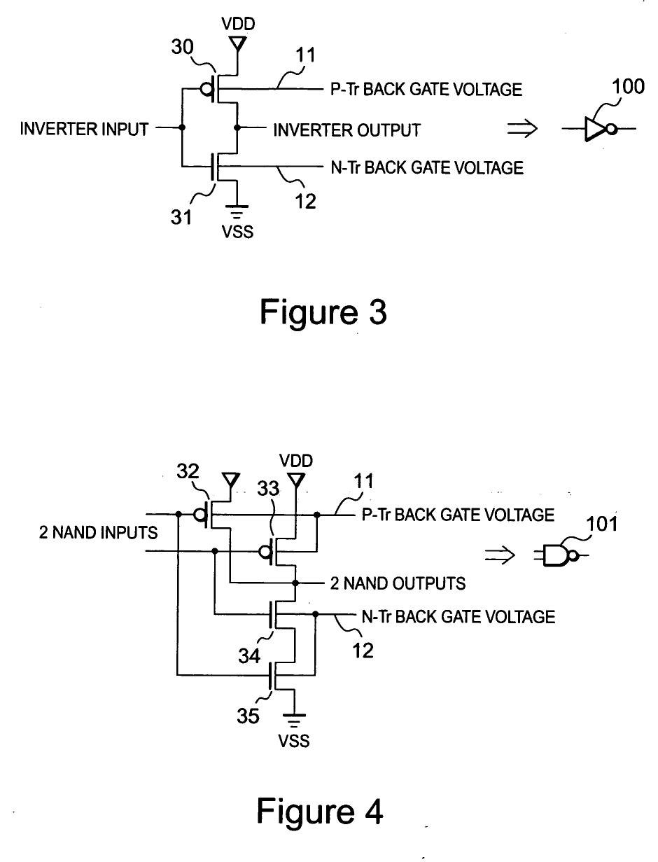

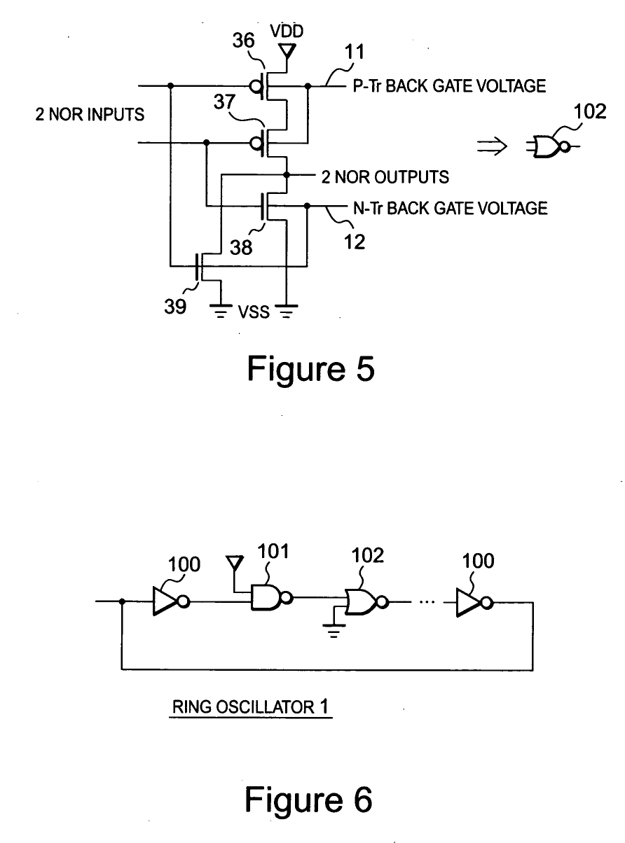

FIGS. 3 to 5 each show an example of delay element 100 forming ring oscillator 1 of FIG. 1. FIG. 3 shows an exemplary CMOS inverter 100 including a P-channel transistor 30 and an N-channel transistor 31. FIG. 4 shows an exemplary two-input NAND 101 including P-channel transistors 32 and 33, and N-channel transistors 34 and 35. FIG. 5 shows an exemplary two-input NOR 102 including P-channel transistors 36 and 37, and N-channel transistors 38 and 39. FIG. 6 shows an example of ring oscillator 1 including the logic circuits (delay elements 100 to 102) each shown in FIGS. 3 to 5.

For example, according to the present invention, adjustment accuracy may be improved. This may be because the adjustment of delay time which is an important exemplary circuit characteristic is performed by using the delay time of the ring oscillator (e.g., the adjustment of delay time is performed by using the oscillation frequency) including the logic path whose delay time is to be considered in the circuit (e.g., IC).

In other words, by using the delay element forming ring oscillator 1, the delay element having the same configuration as the logic circuit element forming the logic circuit within the IC, the difference of effect based on the kind of logic circuit with respect to the back gate voltage control may be reduced, whereby the accuracy in characteristic adjustment may be further improved.

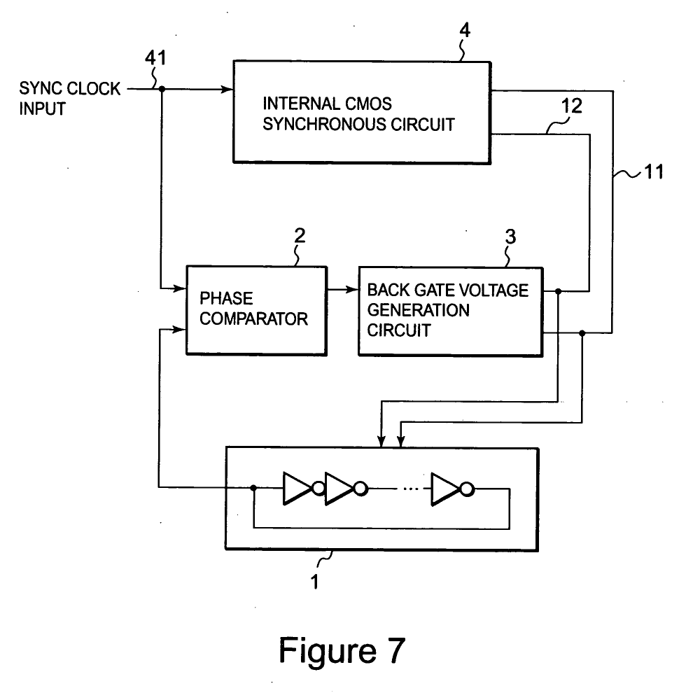

FIG. 7 shows an exemplary block diagram showing another exemplary embodiment of the present invention, and the same reference numerals are applied to parts corresponding to FIG. 1. In this exemplary embodiment, a sync clock input 41 supplied to a semiconductor IC, is used as reference clock input 10 shown in FIG. 1. In this case, the sync clock input 41 is a clock signal used for a CMOS synchronous circuit 4 within the IC.

In the exemplary embodiment shown in FIG. 1, a dedicated reference clock input 10 may be required. However, when the semiconductor IC is a synchronous circuit which operates in synchronization with an external clock, as shown in FIG. 7, and reference clock input 10 (refer to FIG. 1) is used as both a reference clock input and the clock signal used for the synchronous circuit 4, it may be unnecessary to supply the external reference clock input 10 required for the adjustment. Thus, any additional clock supplying circuit and input terminal may not be necessary.

The exemplary embodiment of the present invention is applied to a semiconductor IC using a CMOS logic circuit, but the present invention is widely applicable to semiconductor ICs in the field of digital circuitry, which operate in synchronization with a clock signal, for example.

While this invention has been described with reference to exemplary embodiments, this description is not intended as limiting. Various modifications of the illustrative embodiments, as well as other embodiments of the invention, will be apparent to persons skilled in the art upon taking description as a whole. It is, therefore, contemplated that the appended claims will cover any such modifications or embodiments as fall within the true scope of the invention.

Further, the inventor's intent is to encompass all equivalents of all the elements of the claimed invention even if the claims are amended during prosecution.

This application is based on Japanese Patent Application No. 2005-017560 filed on Jan. 26, 2005 and including specification, claims, drawings and summary. The disclosure of the above Japanese Patent Application is incorporated herein by reference in its entirety.

What is claimed is:

1. A characteristic adjustment circuit for a logic circuit, comprising:
an oscillator that includes a first metal-oxide semiconductor (MOS) transistor and outputs an oscillation output; and
a voltage generator that generates a voltage of a second MOS transistor of said logic circuit according to a phase difference between said oscillation output and a reference signal.

2. The characteristic adjustment circuit according to claim 1, wherein said reference signal includes a reference clock used to operate said logic circuit.

3. The characteristic adjustment circuit according to claim 1, further comprising:
a phase comparator that compares a phase of said oscillation output with a phase of said reference signal.

4. The characteristic adjustment circuit according to claim 1, wherein said first MOS transistor comprises a same type as said second MOS transistor.

5. The characteristic adjustment circuit according to claim 1, wherein said oscillator includes a ring oscillator including a plurality of said first MOS transistors.

6. The characteristic adjustment circuit according to claim 1, wherein said voltage is applied to said oscillator.

7. The characteristic adjustment circuit according to claim 1, wherein said voltage includes a back gate voltage.

8. The characteristic adjustment circuit according to claim 7, wherein said back gate voltage includes:
a P-channel transistor (P-Tr) back gate voltage; and
a N-channel transistor (N-Tr) back gate voltage, wherein:
when said oscillation output is delayed as compared with said reference signal, said P-Tr back gate voltage is raised and said N-Tr back gate voltage is lowered; and
when said oscillation output is advanced as compared with the reference signal, said P-Tr back gate voltage is lowered and said N-Tr back gate voltage is raised.

9. A circuit, comprising:
said logic circuit; and
said characteristic adjustment circuit according to claim 1.

10. A circuit according to claim 9, wherein said logic circuit and said characteristic adjustment circuit are formed on a single semiconductor substrate.

11. A characteristic adjustment circuit, comprising:
a ring oscillator that includes a first metal-oxide semiconductor (MOS) transistor and outputs an oscillation output; and
a voltage generator that generates a voltage of a second MOS transistor of said logic circuit according to said oscillation output.

12. A method of adjusting a characteristic of a logic circuit, comprising:
detecting a phase difference between a reference signal and an oscillation output of an oscillator including a first metal-oxide semiconductor (MOS) transistor; and
generating a voltage of a second MOS transistor of said logic circuit according to said phase difference.

13. The method of adjusting a characteristic of a logic circuit according to claim 12, wherein said reference signal includes a reference clock used to operate the logic circuit.

14. The method of adjusting a characteristic of a logic circuit according to claim 12, further comprising:
comparing a phase of said oscillation output with a phase of said reference signal.

15. The method of adjusting a characteristic of a logic circuit according to claim 12, wherein said first MOS transistor comprises a same type as said second MOS transistor.

16. The method of adjusting a characteristic of a logic circuit according to claim 12, wherein said oscillator includes a ring oscillator including a plurality of said first MOS transistors.

17. The method of adjusting a characteristic of a logic circuit according to claim 12, further comprising:
applying said voltage to said oscillator.

18. The method of adjusting a characteristic of a logic circuit according to claim 12, wherein said voltage includes a back gate voltage.

19. The method of adjusting a characteristic of a logic circuit according to claim 18, wherein said back gate voltage includes:
a P-channel transistor (P-Tr) back gate voltage; and
a N-channel transistor (N-Tr) back gate voltage; wherein:
when said oscillation output is delayed as compared with said reference signal, said P-Tr back gate voltage is raised and said N-Tr back gate voltage is lowered; and
when said oscillation output is advanced as compared with the reference signal, said P-Tr back gate voltage is lowered and said N-Tr back gate voltage is raised.

20. A method of adjusting a characteristic of a logic circuit, comprising:
outputting an oscillation output by a ring oscillator including a first metal-oxide semiconductor MOS transistor; and
generating a voltage of said second MOS transistor of said logic circuit according to said oscillation output.
